(19) United States
(12) Patent Application Publication
(10) Pub. No.: US 2022/0381828 A1
(43) Pub. Date: Dec. 1, 2022

(54) ELECTRONIC DEVICE AND CONTROL METHOD THEREOF

(71) Applicant: Chicony Electronics Co., Ltd., New Taipei City (TW)

(72) Inventors: Chien-Tsung CHEN, New Taipei City (TW); Chia-Wei HSU, New Taipei City (TW)

(21) Appl. No.: 17/661,047

(22) Filed: Apr. 28, 2022

(30) Foreign Application Priority Data
May 25, 2021 (TW) 110118936

(51) Int. Cl. G01R 31/327

(52) U.S. Cl. CPC G01R 31/3277

(57) ABSTRACT

The present disclosure provides electronic device and control method thereof. The electronic device includes input circuit and processor. The input circuit includes key switches arranged in array. The processor is coupled to the key switches through column lines and row lines and is configured to: detect part of the row lines and part of the column lines coupled to at least one turned-on key switch; assign one of the part of the row lines and the part of the column lines as scan line group, and assign the other of the part of the row lines and the part of the column lines as return line group; input corresponding scan signal to corresponding scan line of the scan line group; and detect whether the return line group outputs the corresponding scan signal, to confirm position of the at least one turned-on key switch.

### CROSS-REFERENCE TO RELATED APPLICATION

This application claims priority to Taiwan Application Serial Number 110118936, filed May 25, 2021, which is herein incorporated by reference in its entirety.

### BACKGROUND

### Field of Invention

This disclosure relates to the electronic device and control method thereof, and in particular to the electronic device, which has multiple keys, and control method thereof.

### Description of Related Art

For device having multiple keys, it is traditional to confirm whether there is a key being pressed by sequentially scanning each column line. However, traditional scanning method is prone to following problems:

1. When the amount of the column lines is too many, the scan time is relatively long, thereby affecting the scan cycle and the power consumption of the device;

2. When the column lines or the row lines have too much impedance and the charge/discharge time is prolonged consequentially, the signal reading time should be prolonged, thereby affecting the scan cycle and the power consumption of the device.

### SUMMARY

An aspect of present disclosure relates to an electronic device. The electronic device includes an input circuit and a processor. The input circuit includes a plurality of key switches arranged in an array, wherein each of the key switches is configured to change from a turned-off state into a turned-on state in response to a user input. The processor is coupled to the key switches through a plurality of column lines and a plurality of row lines and is configured to: detect a part of the row lines and a part of the column lines coupled to at least one turned-on key switch; assign one of the part of the row lines and the part of the column lines as a scan line group, and assign the other of the part of the row lines and the part of the column lines as a return line group; input a corresponding scan signal of a plurality of scan signals to a corresponding scan line of the scan line group; and detect whether the return line group outputs the corresponding scan signal, to confirm a position of the at least one turned-on key switch.

Another aspect of present disclosure relates to a control method applied to an electronic device, wherein the electronic device includes a processor and an input circuit including a plurality of key switches arranged in an array, and each of the key switches is configured to change from a turned-off state into a turned-on state in response to a user input. The control method includes: by the processor, detecting a part of a plurality of row lines and a part of a plurality of column lines coupled to at least one turned-on key switch; by the processor, assigning one of the part of the row lines and the part of the column lines as a scan line group, and assigning the other of the part of the row lines and the part of the column lines as a return line group; by the processor, inputting a corresponding scan signal of a plurality of scan signals to a corresponding scan line of the scan line group; and by the processor, detecting whether the return line group outputs the corresponding scan signal, to confirm a position of the at least one turned-on key switch.

### BRIEF DESCRIPTION OF THE DRAWINGS

FIG. 1 is a block diagram of an electronic device in accordance with some embodiments of the present disclosure;

FIG. 2 is a circuit diagram of an input circuit of the electronic device in accordance with some embodiments of the present disclosure;

FIG. 3 is a flow diagram of a control method of the electronic device in accordance with some embodiments of the present disclosure;

FIGS. 4A-4C are schematic diagrams of signals in the electronic device during a scan period in accordance with some embodiments of the present disclosure; and

FIG. 5 is a circuit diagram of an input circuit of the electronic device in accordance with other embodiments of the present disclosure.

### DETAILED DESCRIPTION

The embodiments are described in detail below with reference to the appended drawings to better understand the aspects of the present disclosure. However, the provided embodiments are not intended to limit the scope of the disclosure, and the description of the structural operation is not intended to limit the order in which they are performed. Any device that has been recombined by components and produces an equivalent function is within the scope covered by the disclosure.

The terms used in the entire specification and the scope of the patent application, unless otherwise specified, generally have the ordinary meaning of each term used in the field, the content disclosed herein, and the particular content.

The terms “coupled” or “connected” as used herein may mean that two or more elements are directly in physical or electrical contact, or are indirectly in physical or electrical contact with each other. It can also mean that two or more elements interact with each other.

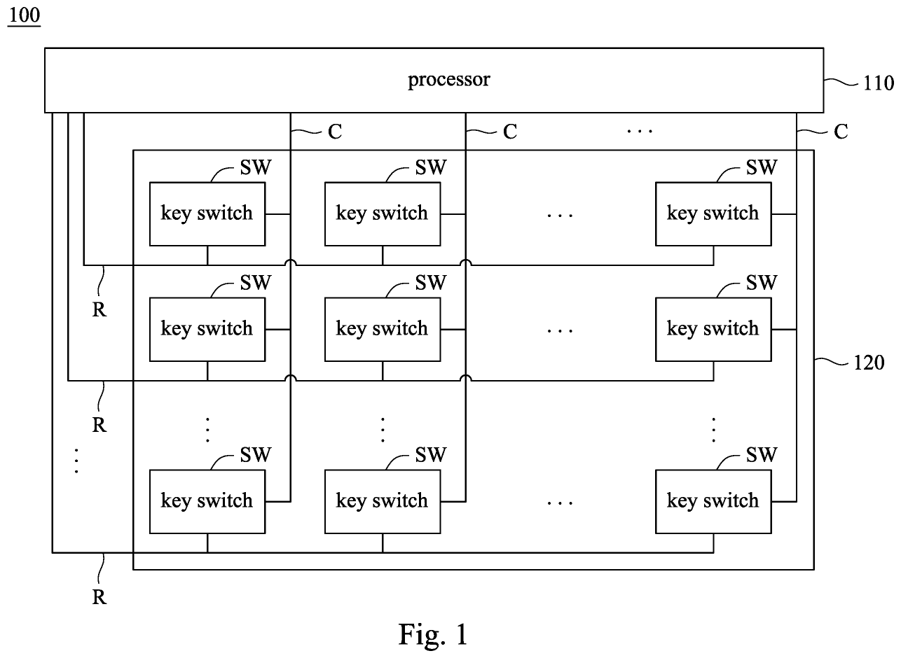

Referring to FIG. 1, FIG. 1 is a block diagram of an electronic device 100 in accordance with some embodiments of the present disclosure. The electronic device 100 includes a processor 110, an input circuit 120, a plurality of row lines R and a plurality of column lines C. In some embodiments, the electronic device 100 can be, for example but not limited to, computer with multiple keys, mobile device, remote controller or phone. In particular, the input circuit 120 includes a plurality of key switches SW arranged in an array, to compose multiple keys of the electronic device 100.

In structure, the processor 110 is coupled to multiple first terminals of a same row of the key switches SW through a corresponding row line R and is coupled to multiple second terminals of the same row of the key switches SW through each of the column lines C. The row lines R and the column lines C are vertically intersected. Each of the key switches SW is arranged between a corresponding row line R and a corresponding column line C.

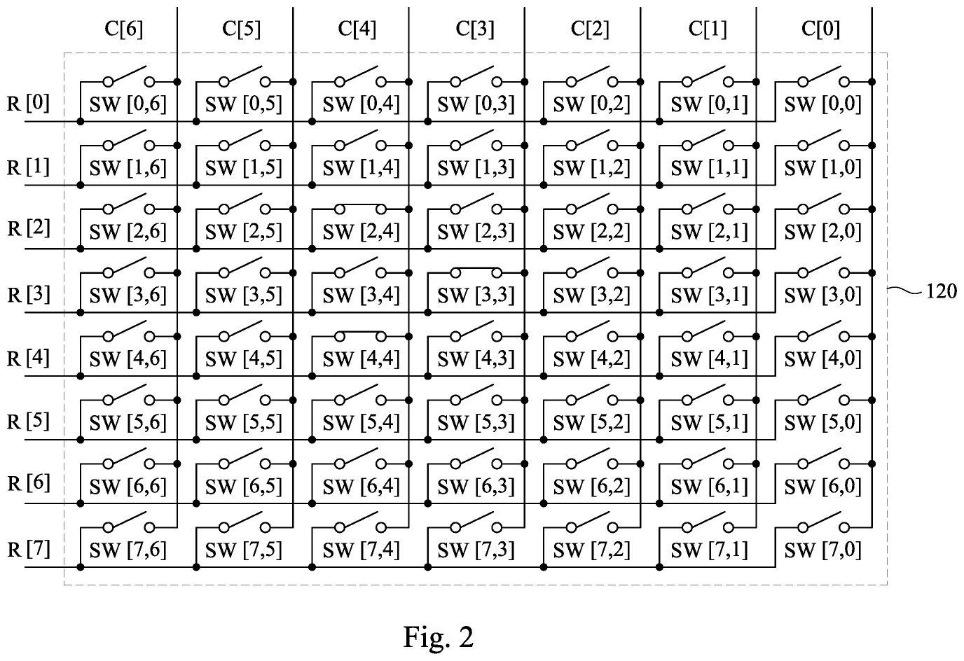

Referring to FIG. 2 together, FIG. 2 is a circuit diagram of the input circuit 120 of the electronic device 100 in accordance with some embodiments of the present disclosure. For simplification of description, FIG. 2 only illustrates 8 row lines R[0]-R[7], 7 column lines C[0]—C[6] and 56 key switches SW[0,0]-SW[7,6], but the present disclosure is not limited herein. As shown in FIG. 2, the row line R[0] is coupled to 7 first terminals of the same row of 7 key switches SW[0,0]-SW[0,6], and the column lines C[0]—C[6] are coupled to 7 second terminals of the same row of 7 key switches SW[0,0]-SW[0,6]. The arrangement of other rows of the key switches SW can be deduced by analogy, and therefore the descriptions thereof are omitted herein.

In some embodiments, each of the key switches SW is in a turned-off state when being idle (for example, when not being pressed by the user). When the user presses the key of the electronic device 100, the key switch SW corresponding to the key being pressed would change from the turned-off state into a turned-on state in response to a user input (e.g., a pressing action), so as to form a loop with the processor 110 through the corresponding row line R and the corresponding column line C. Other key switches SW corresponding to other keys not being pressed are still in the turned-off state, so that the processor 110 is unable to receive/transmit signal through the corresponding row lines R and the corresponding column lines C.

In the present embodiment, the key switches SW can be implemented by a mechanical switch or a membrane switch, and the processor 110 can be implemented by a microprocessor. However, the present disclosure is not limited herein.

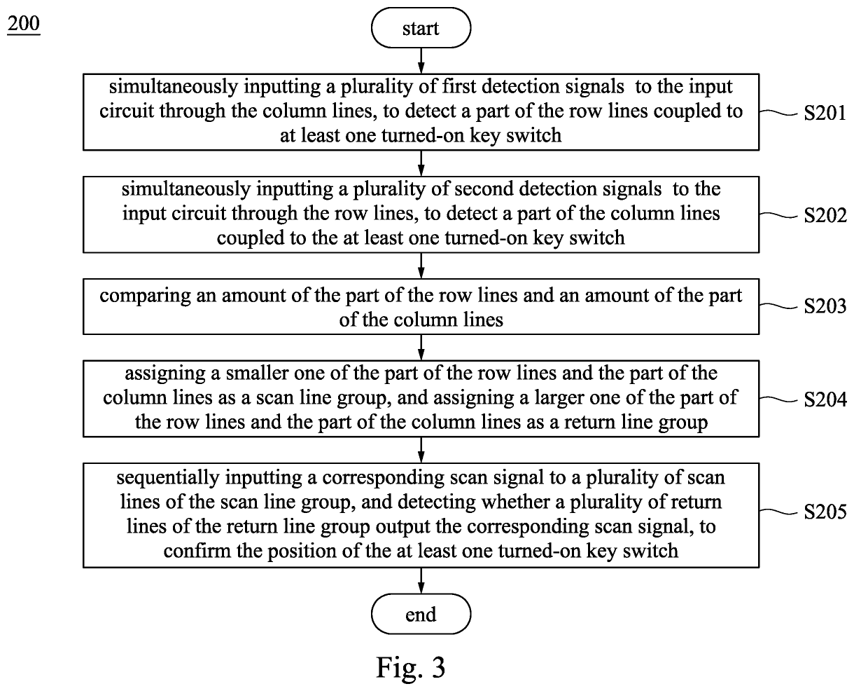

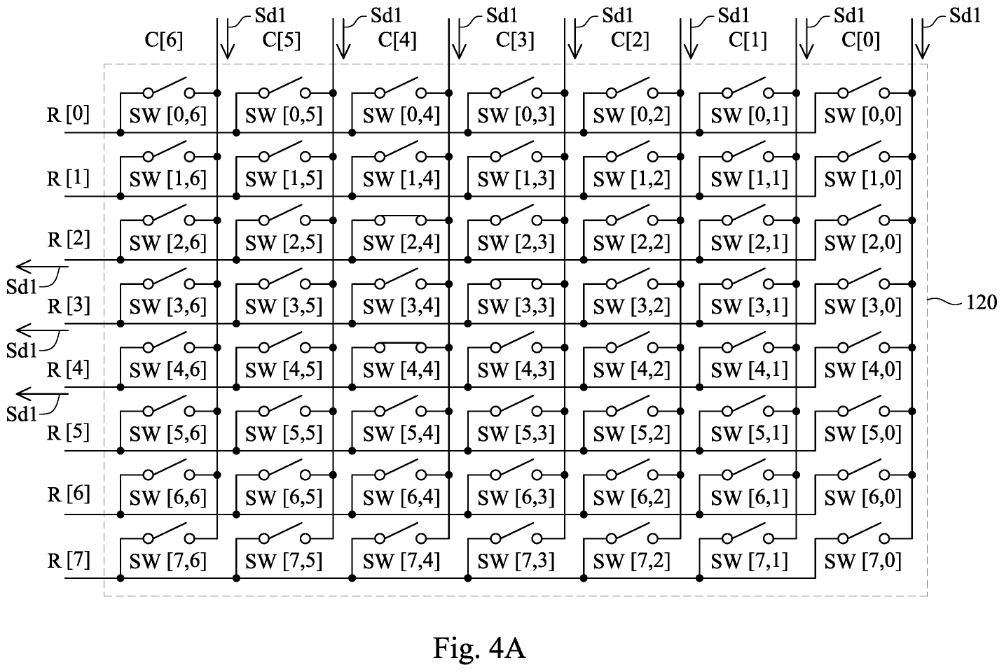

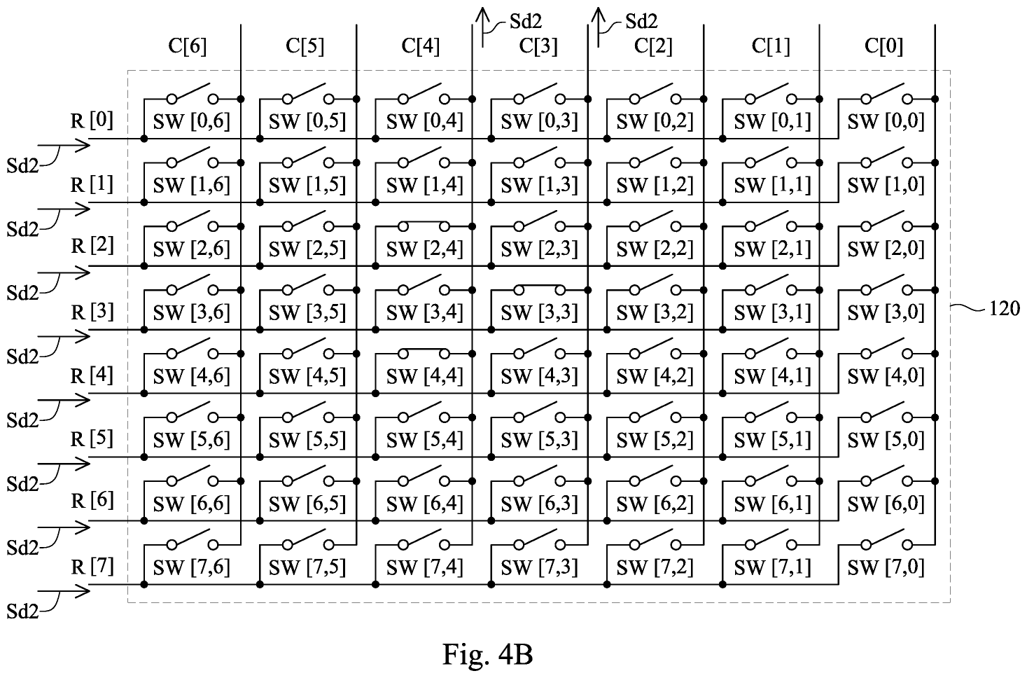

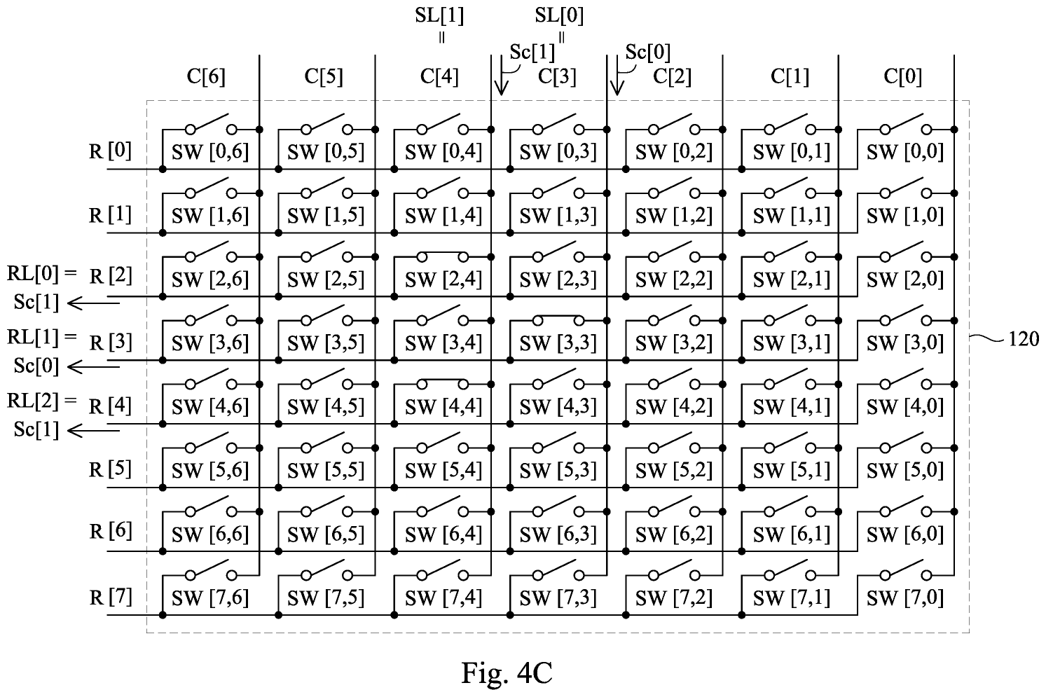

Referring to FIG. 3, FIG. 3 is a flow diagram of a control method 200 in accordance with some embodiments of the present disclosure. The control method 200 can be executed by the processor 110 of the electronic device 100 of FIG. 1, so that the processor 110 can determine whether each key of the electronic device 100 is pressed. In some embodiments, the control method 200 includes operations S201-S205. For convenience of description, the control method 200 would be described below with reference to FIGS. 2 and 4A-4C.

In the embodiment of FIG. 2, the user presses 3 keys corresponding to 3 key switches SW[2,4], SW[3,3] and SW[4,4] in a scan cycle (e.g., 4 ms), so that 3 key switches SW[2,4], SW[3,3] and SW[4,4] are changed from the turned-off state into the turned-on state in response to the user input.

Referring to FIG. 4A together, FIG. 4A is a schematic diagram of signals in the electronic device 100 during a scan period. In operation S201, the processor 110 simultaneously inputs a plurality of first detection signals Sd1 to the input circuit 120 through the column lines C[0]—C[6], and receives the first detection signals Sd1 through 3 row lines R[2]-R[4]. Accordingly, the processor 110 detects 3 row lines R[2]-R[4] coupled to the turned-on key switches SW[2,4], SW[3,3] and SW[4,4] (that is, detect a part of the row lines coupled to at least one turned-on key switch). In the present embodiment, the amount (e.g., 7) of the first detection signals Sd1 is equal to the amount of the column lines C.

Referring to FIG. 4B together, FIG. 4B is a schematic diagram of signals in the electronic device 100 during the scan period. In operation S202, the processor 110 simultaneously inputs a plurality of second detection signals Sd2 to the input circuit 120 through the row lines R[0]-R[7], and receives the second detection signals Sd2 through 2 column lines C[3]—C[4]. Accordingly, the processor 110 detects 2 column lines C[3]—C[4] coupled to the turned-on key switches SW[2,4], SW[3,3] and SW[4,4] (that is, detect a part of the column lines coupled to the at least one turned-on key switch). In the present embodiment, the amount (e.g., 8) of the second detection signals Sd2 is equal to the amount of the row lines R.

In operation S203, the processor 110 compares the amount of the row lines R which are coupled to the turned-on key switches SW (e.g., the key switches SW[2,4], SW[3,3] and SW[4,4] of FIG. 2) and the amount of the column lines C which are coupled to the turned-on key switches SW. In the embodiment of FIG. 2, the amount of the row lines R which are coupled to the turned-on key switches SW is 3, and the amount of the column lines C which are coupled to the turned-on key switches SW is 2. Accordingly, the processor 110 obtains the result that the amount of the column lines C which are coupled to the turned-on key switches SW is smaller.

Then, in operation S204, the processor 110 assigns one with smaller amount as a scan line group, and assigns one with larger amount as a return line group. Referring to FIG. 4C, FIG. 4C is a schematic diagram of signals in the electronic device 100 during the scan period. As shown in FIG. 4C, the processor 110 assigns the column lines C[3]—C[4] as two scan lines SL[0]-SL[1], and assigns the row lines R[2]-R[4] as 3 return lines RL[0]-RL[2].

In operation S205, the processor 110 sequentially inputs a corresponding scan signal to the scan lines SL, and detects whether the return lines RL output the corresponding scan signal to confirm the specific position of the turned-on key switch SW. The terms “corresponding scan signal” as used herein may mean that the scan signal which is inputted to one specific scan line SL (for example, the scan signals Sc[0] and Sc[1] of FIG. 4C are the scan signals which are inputted to the scan lines SL[0] and SL[1] respectively). It can be appreciated that different scan lines SL can receive same or different scan signals. In the present embodiment, the scan signals (e.g., the scan signals Sc[0] and Sc[1] of FIG. 4C) inputted to each of the scan lines SL are same. In particular, as shown in FIG. 4C, the processor 110 first inputs the scan signal Sc[0] to the scan line SL[0], and receives the scan signal Sc[0] through the return line RL[1] only. Accordingly, the processor 110 determines that there is one turned-on key switch SW[3,3] at the position of 4^{th} column and 4^{th} row. Then, the processor 110 inputs the scan signal Sc[1] to the scan line SL[1], and receives the scan signal Sc[1] through the return lines RL[0] and RL[2]. Accordingly, the processor 110 determines that there are two turned-on key switches SW[2,4] and SW[4,4] at the position of 5^{th} column and 3^{rd} row and the position of 5^{th} column and 5^{th} row respectively. In such way, the processor 110 can obtain the state of each key of the electronic device 100 according to the positions of the turned-on key switches SW[2,4], SW[3,3] and SW[4,4].

In some embodiments, each scan cycle includes a scan period (that is, a period for executing operations S201-S205) and a sleep period. Generally speaking, when the processor 110 finishes the scan operation (that is, the scan period is ended) in one scan cycle, it can enter the sleep period. In some embodiments, in order to avoid the scan result being affected by physical bounce generated because the key is pressed, the processor 110 would confirm the scan result only when obtaining the same scan result in three consecutive scan cycles. The scan result of each scan cycle can be stored in storage (e.g., memory) of the electronic device 100 for the processor 110 to compare the scan results of different scan cycles.

In other embodiments, the processor 110 does not execute operations S203-S204. After operation S202, the processor 110 directly assigns the row lines R[2]-R[4] coupled to the turned-on key switches SW[2,4], SW[3,3] and SW[4,4] as 3 scan lines, and directly assigns the column lines C[3]—C[4] coupled to the turned-on key switches SW[2,4], SW[3,3] and SW[4,4] as 2 return lines. Then, the processor 110 executes operation S205. In operation S205, the processor 110 sequentially inputs the corresponding scan signal to 3 scan lines, and detects whether 2 return lines output the corresponding scan signal to confirm the specific positions of the turned-on key switches SW[2,4], SW[3,3] and SW[4,4].

In particular, the processor 110 first inputs the corresponding scan signal to the first scan line (i.e., the row line R[2]), and receives the corresponding scan signal through the second return line (i.e., the column line C[4]) only. Accordingly, the processor 110 determines that there is one turned-on key switch SW[2,4] at the position of 5^{th} column and 3^{rd} row. The processor 110 then inputs the corresponding scan signal to the second scan line (the row line R[3]), and receives the corresponding scan signal through the first return line (i.e., the column line C[3]) only. Accordingly, the processor 110 determines that there is one turned-on key switch SW[3,3] at the position of 4^{th} column and 4^{th} row. Finally, the processor 110 inputs the corresponding scan signal to the third scan line (the row line R[4]), and receives the corresponding scan signal through the second return line (i.e., the column line C[4]) only. Accordingly, the processor 110 determines that there is one turned-on key switch SW[4,4] at the position of 5^{th} column and 5^{th} row. In such way, the processor 110 can obtain the state of each key of the electronic device 100 according to the positions of the turned-on key switches SW[2,4], SW[3,3] and SW[4,4].

It can be appreciated that in the embodiment that operation S203-S204 are not executed, after operation S202, the processor 110 can also directly assign the column lines C[3]—C[4] coupled to the turned-on key switches SW[2,4], SW[3,3] and SW[4,4] as 2 scan lines, and directly assigns the row lines R[2]-R[4] coupled to the turned-on key switches SW[2,4], SW[3,3] and SW[4,4] as 3 return lines. The scan operation thereof is similar to those of the above embodiments, and therefore the descriptions thereof are omitted herein.

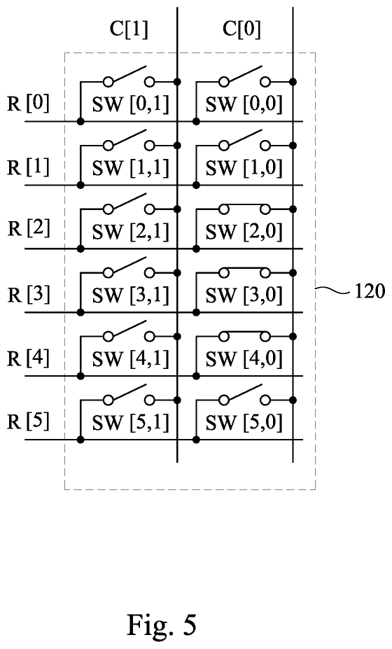

Referring to FIG. 5, FIG. 5 is a circuit diagram of the electronic device 100 in accordance with other embodiments of the present disclosure. For simplification of description, FIG. 5 only illustrates 6 row lines R[0]-R[5], 2 column lines C[0]—C[1] and 12 key switches SW[0,0]-SW[5,1], but the present disclosure is not limited herein. In the embodiment of FIG. 5, the processor 110 executes operation S201 and S202, and detects that there are 1 column line C[0] and 3 row lines R[2]-R[4] coupled to the turned-on key switches SW[2,0], SW[3,0] and SW[4,0]. Accordingly, the processor 110 can omit subsequent operations S203-S205, and directly confirms the specific positions of the turned-on key switches SW[2,0], SW[3,0] and SW[4,0]. In other words, when one of the amount of the row lines R couple to the turned-on key switches SW and the amount of the column lines C coupled to the turned-on key switches SW is 1, the processor 110 can directly confirm the specific positions of the turned-on key switches SW, so as to dramatically reduce the scan time and scan number.

In comparison with the traditional scan method which sequentially scans each row of the key switch, the electronic device 100 of the present disclosure first detects the approximate area where the turned-on key switches are in the switch array, and then performs the scan operation on the detected area to confirm the specific positions of the turned-on key switches. In such way, the electronic device 100 of the present disclosure can shorten the scan period of each scan cycle. In the condition that the scan cycle is fixed, the sleep period can be relatively increased to reduce the power consumption of the electronic device 100, thereby achieving the effect of power saving (which is especially important for wireless electronic device).

Some electronic devices are limited by their structure (for example, circuits printed with carbon ink) to have long charge/discharge time, thereby often being unable to read signals because the scan cycle is too short. In the condition that the scan cycle is fixed, the electronic device 100 of the present disclosure can provide enough signal reading time due to the simplification of scan operation, so that the signal can be stably read.

In addition, since the scan frequency can be increased (that is, the scan cycle is shortened) due to the shortened scan period, the control method 200 of the present disclosure is also applicable to the electronic devices requiring low latency.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present invention cover modifications and variations of this invention provided they fall within the scope of the following claims.

What is claimed is:

1. An electronic device, comprising:
an input circuit comprising a plurality of key switches arranged in an array, wherein each of the key switches is configured to change from a turned-off state into a turned-on state in response to a user input;
a processor coupled to the key switches through a plurality of column lines and a plurality of row lines and configured to:
detect a part of the row lines and a part of the column lines coupled to at least one turned-on key switch;
assign one of the part of the row lines and the part of the column lines as a scan line group, and assign the other of the part of the row lines and the part of the column lines as a return line group;
input a corresponding scan signal of a plurality of scan signals to a corresponding scan line of the scan line group; and
detect whether the return line group outputs the corresponding scan signal, to confirm a position of the at least one turned-on key switch.

2. The electronic device of claim 1, wherein detecting the part of the row lines and the part of the column lines comprises:
simultaneously inputting a plurality of first detecting signals through the column lines; and
receiving a part of the first detecting signals through the part of the row lines, to detect the part of the row lines.

3. The electronic device of claim 2, wherein detecting the part of the row lines and the part of the column lines further comprises:
simultaneously inputting a plurality of second detecting signals through the row lines; and
receiving a part of the second detecting signals through the part of the column lines, to detect the part of the column lines.

4. The electronic device of claim 1, wherein assigning the scan line group and the return line group comprises:
comparing an amount of the part of the row lines and an amount of the part of the column lines.

5. The electronic device of claim 4, wherein assigning the scan line group and the return line group further comprises:
assigning a smaller one of the part of the row lines and the part of the column lines as the scan line group, and assigning a larger one of the part of the row lines and the part of the column lines as the return line group.

6. The electronic device of claim 1, wherein assigning the scan line group and the return line group comprises:
directly assigning the part of the row lines as the scan line group, and directly assigning the part of the column lines as the return line group.

7. The electronic device of claim 1, wherein assigning the scan line group and the return line group comprises:
directly assigning the part of the column lines as the scan line group, and directly assigning the part of the row lines as the return line group.

8. The electronic device of claim 1, wherein after detecting the part of the row lines and the part of the column lines, the processor is further configured to:
directly confirm the position of the at least one turned-on key switch if one of the amount of the part of the row lines and the amount of the part of the column lines is 1.

9. The electronic device of claim 1, wherein the column lines and the row lines are vertically intersected, and a corresponding key switch of the key switches is arranged between a corresponding row line of the row lines and a corresponding column line of the column lines.

10. A control method applied to an electronic device, wherein the electronic device comprises a processor and an input circuit comprising a plurality of key switches arranged in an array, each of the key switches is configured to change from a turned-off state into a turned-on state in response to a user input, and the control method comprises:
by the processor, detecting a part of a plurality of row lines and a part of a plurality of column lines coupled to at least one turned-on key switch;
by the processor, assigning one of the part of the row lines and the part of the column lines as a scan line group, and assigning the other of the part of the row lines and the part of the column lines as a return line group;
by the processor, inputting a corresponding scan signal of a plurality of scan signals to a corresponding scan line of the scan line group; and
by the processor, detecting whether the return line group outputs the corresponding scan signal, to confirm a position of the at least one turned-on key switch.

11. The control method of claim 10, wherein detecting the part of the row lines and the part of the column lines comprises:
by the processor, simultaneously inputting a plurality of first detecting signals to the column lines; and
by the processor, receiving a part of the first detecting signals from the part of the row lines, to detect the part of the row lines.

12. The control method of claim 11, wherein detecting the part of the row lines and the part of the column lines further comprises:
by the processor, simultaneously inputting a plurality of second detecting signals to the row lines; and
by the processor, receiving a part of the second detecting signals from the part of the column lines, to detect the part of the column lines.

13. The control method of claim 10, wherein assigning the scan line group and the return line group comprises:
by the processor, comparing an amount of the part of the row lines and an amount of the part of the column lines.

14. The control method of claim 13, wherein assigning the scan line group and the return line group further comprises:
by the processor, assigning a smaller one of the part of the row lines and the part of the column lines as the scan line group, and assigning a larger one of the part of the row lines and the part of the column lines as the return line group.

15. The control method of claim 10, wherein assigning the scan line group and the return line group comprises:
by the processor, directly assigning the part of the row lines as the scan line group, and directly assigning the part of the column lines as the return line group.

16. The control method of claim 10, wherein assigning the scan line group and the return line group comprises:
by the processor, directly assigning the part of the column lines as the scan line group, and directly assigning the part of the row lines as the return line group.

17. The control method of claim 10, wherein after detecting the part of the row lines and the part of the column lines, the control method further comprises:
by the processor, directly confirm the position of the at least one turned-on key switch if one of the amount of the part of the row lines and the amount of the part of the column lines is 1.

18. The control method of claim 10, wherein the column lines and the row lines are vertically intersected, and a corresponding key switch of the key switches is arranged between a corresponding row line of the row lines and a corresponding column line of the column lines.
